(19) United States
(12) Patent Application Publication
(10) Pub. No.: US 2026/0065949 A1
(43) Pub. Date: Mar. 5, 2026

(54) MEMORY DEVICES AND METHODS OF MANUFACTURING THEREOF

(71) Applicant: Taiwan Semiconductor Manufacturing Company, Ltd., Hsinchu (TW)

(72) Inventors: Sheng-Po Huang, New Taipei City (TW); Yorinobu Fujino, Hsinchu City (TW); Yumito Aoyagi, Hsinchu City (TW); Ku-Feng Lin, Hsinchu City (TW); Yi-Chun Shih, Hsinchu City (TW)

(73) Assignee: Taiwan Semiconductor Manufacturing Company, Ltd., Hsinchu (TW)

(21) Appl. No.: 19/045,904

(22) Filed: Feb. 5, 2025

Related U.S. Application Data
(60) Provisional application No. 63/688,507, filed on Aug. 29, 2024.

(51) Int. Cl. G11C 5/06; H10B 10/00; H10B 61/00; H10B 63/00; H10B 63/10

(52) U.S. Cl. CPC G11C 5/063; H10B 10/15; H10B 10/18; H10B 61/10; H10B 61/22; H10B 63/10; H10B 63/30

(57) ABSTRACT

A memory device includes a memory array including a plurality of first memory cells physically arranged over a plurality of rows and a plurality of first columns. Each of the plurality of first memory cells includes a memory transistor serially coupled to a memory resistor. The memory device includes one additional row arranged next to the memory array. The additional row includes a plurality of first shunt components, and each of the plurality of first shunt components includes a shunt transistor and a shunt resistor. Respective first source/drain terminals of the shunt transistors of the first shunt components are electrically coupled to one another, and respective second source/drain terminals of the shunt transistors of the first shunt components are electrically coupled to one another and further electrically coupled to respective first source/drain terminals of the memory transistors of the first memory cells.

### CROSS-REFERENCE TO RELATED APPLICATION

This application claims priority to and the benefit of U.S. Provisional Application No. 63/688,507, filed Aug. 29, 2024, entitled “Controllable source-line shunt for 1TIR memory design,” which is incorporated herein by reference in its entirety for all purposes.

### BACKGROUND

The semiconductor integrated circuit (IC) industry has experienced exponential growth. As ICs continue to scale down, more devices are integrated into the single chip. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory device (or circuit), in accordance with some embodiments.

FIG. 2 illustrates a circuit diagram of an example memory device (or circuit), in accordance with some embodiments.

FIG. 3A and FIG. 3B illustrate circuit diagrams of an example memory device (or circuit), in accordance with some embodiments.

FIG. 4 illustrates an example structure associated with a memory device (or circuit), in accordance with some embodiments.

FIG. 5 illustrates a circuit diagram of an example memory device (or circuit), in accordance with some embodiments.

FIG. 6 illustrates a block diagram of an example memory device (or circuit), in accordance with some embodiments.

FIG. 7 illustrates a flow chart of an example method for forming a memory device, in accordance with some embodiments.

FIG. 8 illustrates a flow chart of an example method for operating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, the Common Source Line (CSL) structure is used to reduce source-line (SL) resistance, enabling higher write currents for faster data operations. However, the number of shared SLs is limited by power consumption and speed considerations, especially during write-1 operations, as excessive charging of the SL to the write voltage can hinder performance. Although Magnetic Tunnel Junction-One-Time Programmable (MTJ-OTP) devices can be used, a significant amount of write current is consumed to switch the magnetic states of the cells, which limits the overall performance of both the memory cells and the shared source lines. This further limits the number of shared SLs, making it challenging to exceed the breakdown threshold. While applying a higher voltage bias can provide sufficient write current, it raises reliability concerns for the transistors, potentially impacting their long-term stability and performance.

The present disclosure provides techniques for addressing the abovementioned challenges, such as to reduce the SL resistance. As disclosed herein, in some embodiments, the techniques include a memory array including a plurality of memory cells arranged over a plurality of rows and a plurality of columns, and one additional row arranged next to the memory array. The additional row includes a plurality of shunt components, each of which includes a shunt transistor and a shunt resistor. In some embodiments, gate terminals of selected transistors can be connected to enable signals (e.g., shunt enable), and via structures can be removed to disconnect bit lines, while connecting a metallization layer for SL shunt. By controlling the shunt components, the write-path resistance can be reduced to increase the write current, while the read-path resistance can be reduced to improve the read window.

The techniques can be applicable to any type of memory array that includes SL structures, including but not limited to, 1T-1R memories, N-channel Metal-Oxide-Semiconductor (NMOS), P-channel MOS (PMOS), CFET, Magnetic Random Access Memory (MRAM), Resistive Random Access Memory (RRAM), Phase Change Random Access Memory (PCRAM), MTJ-OTP, planar, Fin Field-Effect Transistor (FinFET), Gate-All-Around (GAA), back-end MOS processes, back-side power delivery network (BSPDN), super power rail (SPR), computing-in-memory (CIM) design, etc.

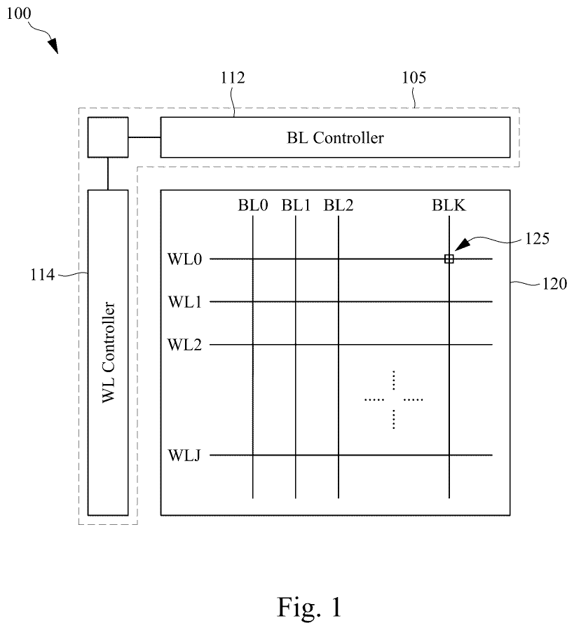

FIG. 1 illustrates a block diagram of an example memory device (or circuit) 100, in accordance with some embodiments. The memory device 100 includes a memory controller 105 and a memory array 120. In one aspect, the memory array 120 includes a plurality of storage circuits or memory cells 125. The memory array 120 further includes word lines WL₀, WL₁ . . . . WL_{J}, each extending in a direction (e.g., X-direction) and bit lines BL₀, BL₁ . . . . BL_{K}, each extending in another direction (e.g., Y-direction). The word lines WLs and the bit lines BLs may each be a conductive metal or conductive rail. In some embodiments, each memory cell 125 is coupled to a corresponding word line WL and a corresponding bit line BL, and can be operated according to voltages or currents through the corresponding word line WL and the corresponding bit line BL. In some embodiments, each bit line includes bit lines BL, BLB coupled to one or more memory cells 125 of a group of memory cells 125 disposed along the direction (e.g., Y-direction). The bit lines BL, BLB may receive and/or provide differential signals.

Each memory cell 125 may include a volatile memory cell, a non-volatile memory cell, or a combination of them. For example, each memory cell 125 is embodied as a static random access memory (SRAM) cell, etc. However, it should be appreciated that the memory cell 125 can be implemented as any of various other non-volatile memory cells such as, for example, a resistive random access memory (RRAM) cell, a magnetoresistive random access memory (MRAM) cell, a phase-change random access memory (PCRAM) cell, an eFuse, an anti-fuse, etc., while remaining within the scope of the present disclosure. In some embodiments, the memory array 120 includes additional lines (e.g., select lines, reference lines, reference control lines, power rails, etc.).

The memory controller 105 is a hardware component that controls operations of the memory array 120. In some embodiments, the memory controller 105 includes a bit line (BL) controller 112, a word line (WL) controller 114, etc. The BL controller 112 and the WL controller 114 may be embodied as logic circuits, analog circuits, or a combination of them. In one configuration, the WL controller 114 can be a circuit that provides a voltage or current through one or more word lines WLs of the memory array 120. The BL controller 112 can be a circuit that provides or senses a voltage or current through one or more bit lines BLs of the memory array 120. The BL controller 112 may be coupled to bit lines BLs of the memory array 120, and the WL controller 114 may be coupled to word lines WLs of the memory array 120.

In some embodiments, the memory array 120 can include a plurality of first memory cells physically arranged over a plurality of rows and a plurality of first columns. Each of the plurality of first memory cells includes a memory transistor serially coupled to a memory resistor. In some embodiments, the memory device 100 can include an additional row arranged next to the memory array 120. The additional row includes a plurality of shunt components. Each of the plurality of shunt components can include a shunt transistor and a shunt resistor. In some embodiments, respective first source/drain terminals of the shunt transistors of the shunt components can be electrically coupled to one another. Respective second source/drain terminals of the shunt transistors of the shunt components can be electrically coupled to one another and further electrically coupled to respective first source/drain terminals of the memory transistors of the first memory cells.

In some embodiments, the memory array 120 can include a first memory cell including a first memory transistor serially connected to a first memory resistor. The first memory transistor include a first source/drain terminal, a second source/drain terminal, and a gate terminal. The memory array 120 can include a second memory cell including a second memory transistor serially connected to a second memory resistor. The second memory cell include a first source/drain terminal, a second source/drain terminal, and a gate terminal. In some embodiments, the memory device 100 can include a first shunt component and a second shunt component. The first shunt component includes a first shunt transistor and a first shunt resistor. The first shunt transistor includes a first source/drain terminal, a second source/drain terminal, and a gate terminal. The second shunt component includes a second shunt transistor and a second shunt resistor. The second shunt transistor includes a first source/drain terminal, a second source/drain terminal, and a gate terminal. In some embodiments, the first source/drain terminal of the first shunt transistor and the first source/drain terminal of the second shunt transistor can be electrically couped to each other. The second source/drain terminal of the first shunt transistor can be electrically connected to the first source/drain terminal of the first memory transistor. The second source/drain terminal of the second shunt transistor can be electrically connected to the first source/drain terminal of the second memory transistor. The first source/drain terminal of the first memory transistor and the first source/drain terminal of the second memory transistor can be electrically coupled to each other.

In some embodiments, the memory cells 125 of the memory array 120 can each include a magnetoresistive random access memory (MRAM) cell, a resistive random access memory (RRAM) cell, or a phase change random access memory (PCRAM) cell. In some embodiments, the memory array 120 can be or part of a CIM array.

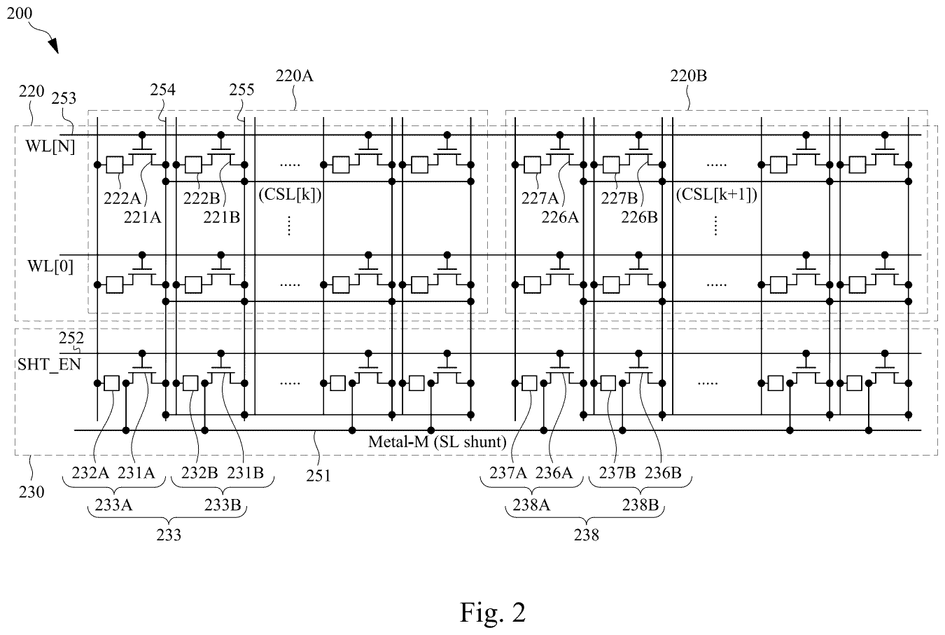

FIG. 2 illustrates a circuit diagram of an example memory device (or circuit) 200, in accordance with some embodiments. In some embodiments, the memory device 200 may be substantially similar to or incorporate features of the memory device 100. The memory device 200 includes a memory array 220, which can be substantially similar to or incorporate features of the memory array 120. The memory device 200 includes one additional row 230. It should be appreciated that the memory device 200 of FIG. 2 is simplified for illustrative purposes, and thus, can be implemented as any of various other configurations while remaining within the scope of the present disclosure.

In some embodiments, the memory array 220 includes a plurality of first memory cells 220A physically arranged over a plurality of rows and a plurality of first columns. Each of the plurality of first memory cells 220A includes a memory transistor serially coupled to a memory resistor. For example, as shown, the plurality of first memory cells 220A of the memory array 220 includes a first memory cell including a first memory transistor 221A serially connected to a first memory resistor 222A. The first memory transistor 221A includes a first source/drain terminal, a second source/drain terminal, and a gate terminal. The plurality of first memory cells 220A of the memory array 220 includes a second memory cell including a second memory transistor 221B serially connected to a second memory resistor 222B. The second memory transistor includes a first source/drain terminal, a second source/drain terminal, and a gate terminal.

In some embodiments, the additional row 230 is arranged next to the memory array 220. The additional row 230 includes a plurality of first shunt components 233 (e.g., first and second shunt components 233A, 233B, etc.). Each of the plurality of first shunt components 233 includes a shunt transistor and a shunt resistor. For example, as shown, the first shunt component 233A includes a first shunt transistor 231A and a first shunt resistor 232A. The first shunt transistor 231A includes a first source/drain terminal, a second source/drain terminal, and a gate terminal. The second shunt component 233B includes a second shunt transistor 231B and a second shunt resistor 232B. The second shunt transistor 231B includes a first source/drain terminal, a second source/drain terminal, and a gate terminal.

In some embodiments, as shown in FIG. 2, respective first source/drain terminals of the shunt transistors of the first shunt components 233 can be electrically coupled to one another. For example, as shown, the first source/drain terminal of the first shunt transistor 231A and the first source/drain terminal of the second shunt transistor 231B are electrically couped to each other. In some embodiments, the first source/drain terminal of the first shunt transistor 231A and the first source/drain terminal of the second shunt transistor 231B can be electrically couped to each other with a first metal track 251. The gate terminal of the first shunt transistor 231A and the gate terminal of the second shunt transistor 231B can be electrically couped to each other with a second metal track 252. The gate terminal of the first memory transistor 221A and the gate terminal of the second memory transistor 221B can be electrically couped to each other with a third metal track 253. The first source/drain terminal of the first memory transistor 221A can be electrically coupled to a fourth metal track 254. The first source/drain terminal of the second memory transistor 221B can be electrically coupled to a fifth metal track 255.

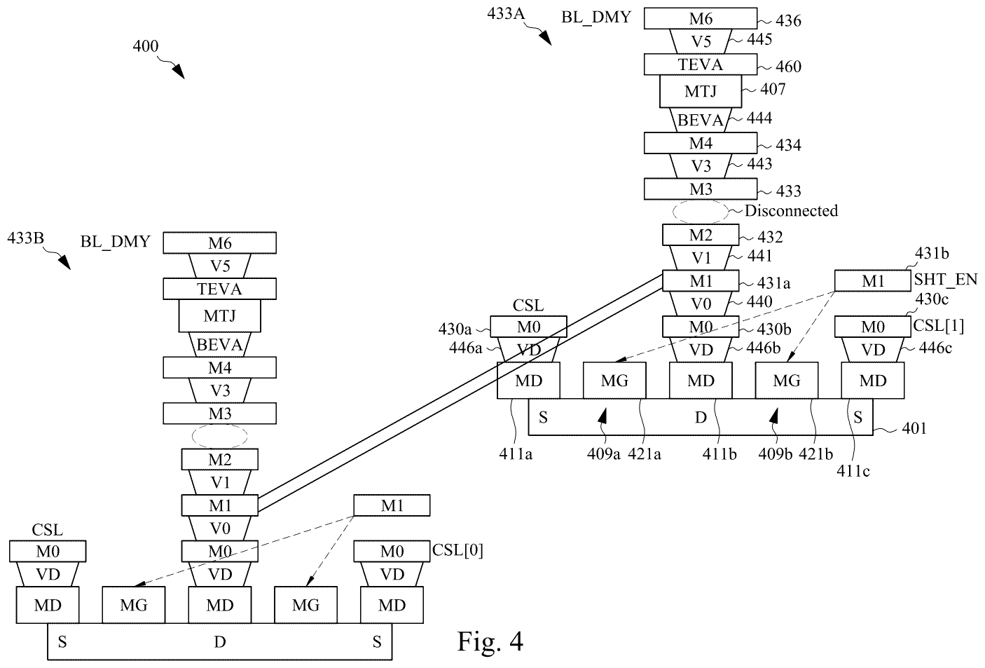

In some embodiments, the fourth metal track 254 and the fifth metal track 255 can be arranged in parallel with each other. In some embodiments, the fourth metal track 254 and the fifth metal track 255 can be electrically coupled to each other, as discussed in greater detail below. In some embodiments, the fourth metal track 254 and the fifth metal track 255 can be formed in a first metallization layer (e.g., M0 as shown in FIG. 4). In some embodiments, the first metal track 251, the second metal track 252, and the third metal track 253 can be arranged in parallel with one another. In some embodiments, the first metal track 251, the second metal track 252, and the third metal track 253 can be formed in a second metallization layer (e.g., M1 as shown in FIG. 4).

In some embodiments, respective second source/drain terminals of the shunt transistors of the first shunt components 233 can be electrically coupled to one another. For example, as shown, the second source/drain terminal of the first shunt transistor 231A and the second source/drain terminal of the second shunt transistor 231B are electrically couped to each other. In some embodiments, respective second source/drain terminals of the shunt transistors of the first shunt components 233 can be electrically coupled to respective first source/drain terminals of the memory transistors of the first memory cells 220A. For example, as shown, the second source/drain terminal of the first shunt transistor 231A is electrically connected to the first source/drain terminal of the first memory transistor 221A. The second source/drain terminal of the second shunt transistor 231B is electrically connected to the first source/drain terminal of the second memory transistor 221B. The first source/drain terminal of the first memory transistor 221A and the first source/drain terminal of the second memory transistor 221B can be electrically coupled to each other.

In some embodiments, the memory device 200 can include a plurality of source lines. The plurality of source lines can be or be formed in the first metallization layer (e.g., M0 as shown in FIG. 4). In some embodiments, the plurality of source lines can be or include the fourth metal track 254, the fifth metal track 255, etc. In some embodiments, the plurality of source lines can be electrically coupled to one another and physically arranged along the first columns, respectively. For example, a first source line can be the fourth metal track 254 arranged along a first one of the first columns. A second source line can be the fifth metal track 255 arranged along a second one of the first columns. In some embodiments, each of the source lines can be electrically coupled to the respective first source/drain terminals of the memory transistors of the first memory cells and to the respective second source/drain terminal of the shunt transistor of the first shunt component, that are arranged along a respective one of the first columns. For example, the first source line (e.g., the fourth metal track 254) can be electrically coupled to the first source/drain terminals of the memory transistor 221A of the first memory cells 220A and to the second source/drain terminal of the shunt transistor 231A of the first shunt component 233A, that are arranged along the first one of the first columns. The second source line (e.g., the fifth metal track 255) can be electrically coupled to the first source/drain terminals of the memory transistor 221B of the first memory cells 220A and to the second source/drain terminal of the shunt transistor 231B of the second shunt component 233B, that are arranged along the second one of the first columns.

In some embodiments, the third metal track 253 can be configured to receive a word line assertion signal (e.g., WL[N]). In some embodiments, the second metal track 252 can be configured to receive a shunt enable signal SHT_EN. In some embodiments, respective gate terminals of the shunt transistors (e.g., the shunt transistors 231A, 231B, etc.) of the first shunt components 233 can be electrically coupled to one another. In some embodiments, the respective gate terminals of the shunt transistors (e.g., the shunt transistors 231A, 231B, etc.) of the first shunt components 233 can be configured to receive the shunt enable signal SHT_EN. As discussed in greater detail below, the shunt enable signal SHT_EN can be configured at a first logic state to enable shunting the source lines with the shunt transistors (e.g., the shunt transistors 231A, 231B, etc.) of the first shunt components 233, when reading the first memory cells 230A or writing a second logic state to the first memory cells 230A.

In some embodiments, the shunt transistor and the shunt resistor of each of the first shunt components 233 can be electrically disconnected from each other. For example, as shown in FIG. 2, the shunt transistor 231A is electrically disconnected from the shunt resistor 232A. The shunt transistor 231B is electrically disconnected from the shunt resistor 232B. This can reduce the write current, thereby saving power and preventing higher IR drop.

In some embodiments, the memory array 220 includes a plurality of second memory cells 220B physically arranged over a plurality of rows and a plurality of second columns. As shown, the plurality of second memory cells 220B can share the plurality of rows with the plurality of first memory cells 220A. Each of the plurality of second memory cells 220B includes a memory transistor serially coupled to a memory resistor. For example, as shown, the plurality of second memory cells 220B of the memory array 220 includes a first memory cell including a first memory transistor 226A serially connected to a first memory resistor 227A. The first memory transistor 226A includes a first source/drain terminal, a second source/drain terminal, and a gate terminal. The plurality of second memory cells 220B of the memory array 220 includes a second memory cell including a second memory transistor 226B serially connected to a second memory resistor 227B. The second memory transistor includes a first source/drain terminal, a second source/drain terminal, and a gate terminal.

The additional row 230 includes a plurality of second shunt components 238 (e.g., first and second shunt components 238A, 238B, etc.). Each of the plurality of second shunt components 238 includes a shunt transistor and a shunt resistor. For example, as shown, the first shunt component 238A includes a first shunt transistor 237A and a first shunt resistor 236A. The first shunt transistor 235A includes a first source/drain terminal, a second source/drain terminal, and a gate terminal. The second shunt component 238B includes a second shunt transistor 236B and a second shunt resistor 237B. The second shunt transistor 236B includes a first source/drain terminal, a second source/drain terminal, and a gate terminal.

In some embodiments, respective first source/drain terminals of the shunt transistors of the second shunt components 238 can be electrically coupled to one another. For example, the first source/drain terminal of the first shunt transistor 235A of the second shunt components 238 can be electrically coupled to the first source/drain terminal of the second shunt transistor 236B of the second shunt components 238. In some embodiments, respective second source/drain terminals of the shunt transistors of the second shunt components 238 can be electrically coupled to one another. For example, as shown, the second source/drain terminal of the first shunt transistor 235A and the second source/drain terminal of the second shunt transistor 236B of the second shunt components 238 can be electrically couped to each other. In some embodiments, respective second source/drain terminals of the shunt transistors of the second shunt components 238 can be electrically coupled to respective first source/drain terminals of the memory transistors of the second memory cells 220B.

For example, as shown, the second source/drain terminal of the first shunt transistor 235A of the first shunt component 238A of the second shunt components 238 can be electrically connected to the first source/drain terminal of the first memory transistor 226A. The second source/drain terminal of the second shunt transistor 236B of the second shunt component 238B of the second shunt components 238 can be electrically connected to the first source/drain terminal of the second memory transistor 226B. The first source/drain terminal of the first memory transistor 226A and the first source/drain terminal of the second memory transistor 226B in the second memory cells 220B can be electrically coupled to each other.

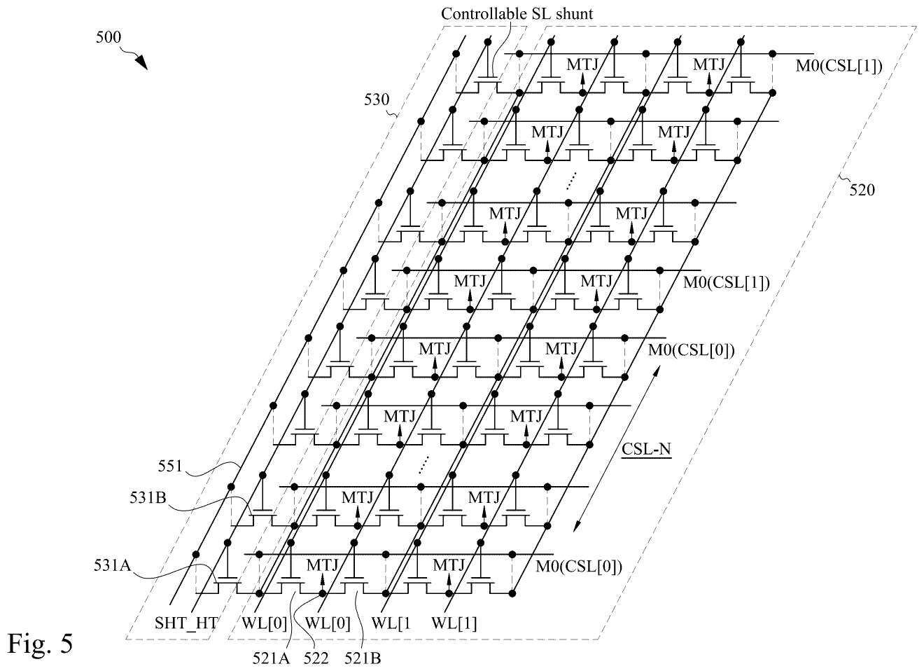

In some embodiments, although depicted as including a single transistor, adjacent ones of the plurality of first memory cells 220A can be commonly connected to a common memory resistor (e.g., as shown in FIG. 5).

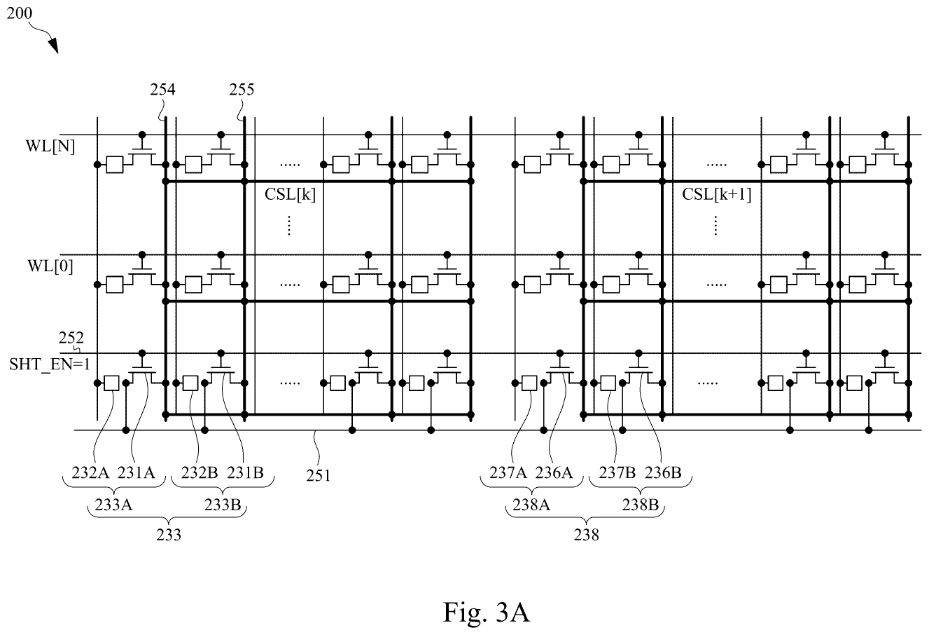

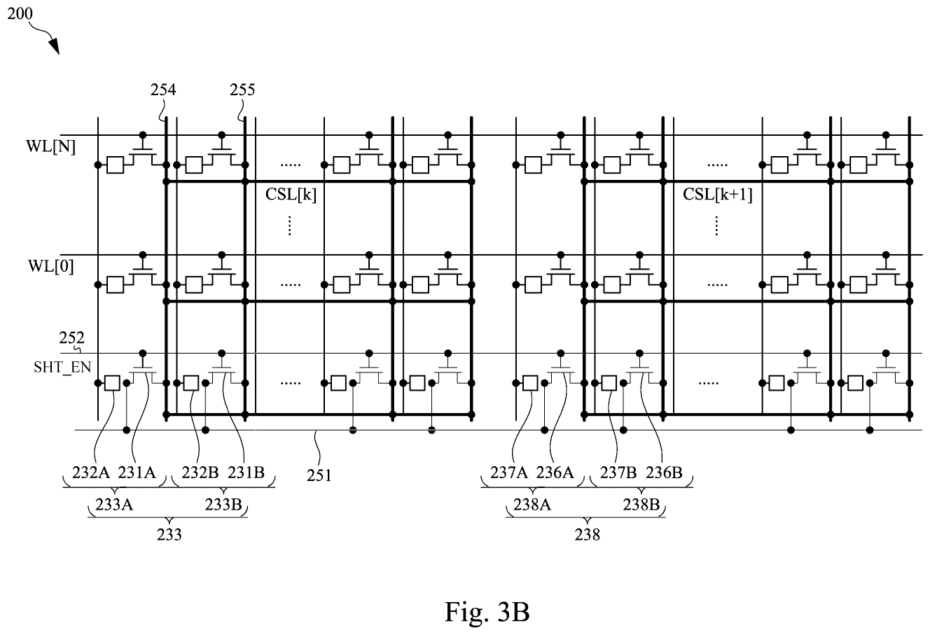

FIG. 3A and FIG. 3B illustrate circuit diagrams of an example memory device (or circuit), in accordance with some embodiments. In some embodiments, the memory device shown in FIG. 3A and FIG. 3B can be the memory device 200. More specifically, the memory device shown in FIG. 3A can be the memory device 200 with a shunt enable signal SHT_EN in a first logic state (e.g., “1”). The memory device shown in FIG. 3B can be the memory device 200 with the shunt enable signal SHT_EN in a second logic state (e.g., “0”). It should be appreciated that the memory device of FIG. 3A and FIG. 3B is simplified for illustrative purposes, and thus, can be implemented as any of various other configurations while remaining within the scope of the present disclosure.

The second metal track 252 can be configured to receive a shunt enable signal SHT_EN. Referring to FIG. 3A, in some embodiments, the shunt enable signal SHT_EN can be configured at a first logic state (e.g., “1”). When the shunt enable signal SHT_EN is provided at the first logic state, the fourth metal track 254 and the fifth metal track 255 can be electrically coupled to the first metal track 251. The shunt enable signal SHT_EN at the first logic state (e.g., “1”) can enable shunting the source lines (e.g., the fourth metal track 254, the fifth metal track 255, etc.) with the shunt transistors (e.g., the first shunt transistor 231A, the second shunt transistor 231B, etc.) of the first shunt components 233, for example, when reading the first memory cells 220A or writing a second logic state to the first memory cells 220A. This can reduce the source line resistance. For example, with the shunt enable signal SHT_EN provided at the first logic state (e.g., “1”), the common source line CSL-N can become CSL-N*M, where M is a number of CSL-N groups connected by a metal line (e.g., the metal track 251). This can thereby reduce the source line resistance by 1/M.

Referring to FIG. 3B, in some embodiments, the shunt enable signal SHT_EN can be configured at the second logic state (e.g., “0”). When the shunt enable signal SHT_EN is provided at the second logic state, the fourth metal track 254 and the fifth metal track 255 can be electrically decoupled from the first metal track 251. The shunt enable signal SHT_EN at the second logic state (e.g., “0”) can disable shunting the source lines (e.g., the fourth metal track 254, the fifth metal track 255, etc.) with the shunt transistors (e.g., the first shunt transistor 231A, the second shunt transistor 231B, etc.) of the first shunt components 233, for example, when writing the first logic state (e.g., “1”) to the first memory cells 220A. This can disable the common source line (CSL) shunt, which keeps smaller capacitance for faster write and lower power consumption.

In some embodiments, the additional row 230 (e.g., the shunt components 233 formed therein) can be controlled based on a truth table (e.g., Table 1 below). Based on different functions, the shunting can be enabled or disabled. For example, write-0 operation can be defined as a current direction from BL to SL, while write-1 operation can be defined as a current direction from SL to BL. For example, Read/CIM read operation, write-breakdown (Write-BRK) operation, etc. can be defined based on a bit line voltage (V_{BL}), a source line voltage (V_{SL}), etc.

TABLE 1

| Function | SHT_EN | V_{BL} | V_{SL} | Description |
|---|---|---|---|---|
| Read/ | 1 | V_{read} | 0 | Turn on the controllable SL shunt to reduce the SL |
| CIM read | | | | resistance and improve the read margin. |
| Write-0 | 1 | V_{write} | 0 | Turn on the controllable SL shunt to reduce the SL |
| | | | | resistance and increase the write current. |
| Write-1 | 0 | 0 | V_{write} | Turn off the controllable SL shunt to keep the SL |
| | | | | capacitance low and improve the speed and power. |
| Write- | 1 | V_{BRK} | 0 | Turn on the controllable SL shunt to reduce the SL |
| BRK | | | | resistance and increase the write current. |

FIG. 4 illustrates an example structure 400 associated with a memory device (or circuit), in accordance with some embodiments. In some embodiments, the structure 400 can be part of the memory device 100, the memory device 200, etc. For example, the structure 400 can be or be part of the additional row 230, etc. It should be appreciated that the structure 400 of FIG. 4 is simplified for illustrative purposes, and thus, can be implemented as any of various other configurations while remaining within the scope of the present disclosure.

In some embodiments, the structure 400 includes a first shunt component 433A and a second shunt component 433B. In some embodiments, the first shunt component 433A includes a storage device 407 (e.g., MTJ), a first selection device 409a, and a second selection device 409b. In some embodiments, the selection devices 409a and 409b can be a first transistor and a second transistor, respectively (hereinafter referred to as transistors 409a and 409b). In some embodiments, the transistors 409a and 409b can be a shunt transistor (e.g., 231A).

In some embodiments, the storage device 407 can be vertically connected to a metal track M6 436 through a vertical interconnect access (via) V5 445. In some embodiments, the storage device 407 can be vertically connected to the metal track M6 436 through the via V5 445 and a top electrode via (TEVA) 460. The storage device 407 can be vertically connected to a metal track M4 434 through a bottom electrode via (BEVA) 444. The BEVA 444 can be used to carry morphology to the storage device 407. The metal track M4 434 can be vertically connected to a metal track M3 433 through a via V3 443. As shown, the metal track M3 433 can be vertically disconnected from a metal track M2 432. In some embodiments, the transistors 409a and 490b can be thereby disconnected from the storage device 407. The metal track M2 432 can be vertically connected to a metal track M1 431a through a via V1 441. The metal track M1 431a can be vertically connected to a metal track M0 430a through a via V0 440. The metal track M0 430a can be vertically connected a metal contact (MD) track MD 411b through a via VD 446b.

In some embodiments, the transistors 409a and 409b can be disposed in an active region 401. For the transistor 409a, a gate contact (MG) track 421a can serve as a gate contact, a metal contact track 411a can serve as a source contact, and the metal contact track 411b can serve as a drain contact. For the transistor 409b, a gate contact track 421b can serve as a gate contact, a metal contact track 411c can serve as a source contact, and the metal contact track 411b can serve as a drain contact. As such, the storage device 407 can be connected to the transistors 409a and 409b. The metal contact track 411a can be vertically connected to a metal track M0 430a through a via VD 446a. Likewise, the metal contact track 411c can be vertically connected to a metal track M0 430c through a via VD 446c.

In some embodiments, a shunt enable signal SHT_EN can be applied to the metal track M1 431b. The metal track M1 431b can be connected to the gate contact tracks 421a and 421b through connection paths (not shown). As such, the shunt enable signal SHT_EN applied to the metal track M1 431b can selectively turn on or turn off the transistors 409a and 409b.

As shown, the second shunt component 433B can be substantially similar to the first shunt component 433A. In some embodiments, the first shunt component 433A can be electrically connected to the second shunt component 433B through a metal track M1 451. For example, the transistors 409a and 409b can be electrically connected to the second shunt component 433B through the metal track contact MD and the metal track M1 451.

FIG. 5 illustrates a circuit diagram of an example memory device (or circuit) 500, in accordance with some embodiments. In some embodiments, the memory device 500 may be substantially similar to or incorporate features of the memory device 100, the memory device 200, etc. For example, the memory device 500 includes an additional row 530 and a plurality of memory cells 520, which may be substantially similar to or incorporate features of the additional row 230 and the memory cells 220A, respectively. It should be appreciated that the memory device 500 of FIG. 5 is simplified for illustrative purposes, and thus, can be implemented as any of various other configurations while remaining within the scope of the present disclosure.

As shown, the additional row 530 is shown to include a plurality of shunt transistors (e.g., a first shunt transistor 531A, a second shunt transistor 531B, etc.). The shunt transistors can receive a shunt enable signal SHT_EN through respective gate terminals. In FIG. 5, shunt resistors (e.g., the shunt resistor 232A, etc.), which are disconnected from the shunt transistors, are not shown. In some embodiments, the shunt resistors can be omitted. By omitting the shunt resistors (e.g., rather than disconnecting), the device design can be simplified while saving materials costs.

The memory cells 520 are shown to include a plurality of memory transistors (e.g., a first memory transistor 521A, a second memory transistor 521B, etc.) and a plurality of memory resistors (e.g., a first memory resistor 522). In some embodiments, adjacent ones of the plurality of memory cells (e.g., the first memory transistor 521A, the second memory transistor 521B) can be commonly connected to a common memory resistor (e.g., the memory resistor 522).

The shunt enable signal SHT_EN at a first logic state (e.g., “1”) can enable shunting source lines with the shunt transistors (e.g., the first shunt transistor 531A, the second shunt transistor 532B, etc.), for example, when reading the memory cells 520 or writing a second logic state to the memory cells 520. This can reduce the source line resistance. For example, with the shunt enable signal SHT_EN provided at the first logic state (e.g., “1”), the common source line CSL-N can become CSL-N*M, where M is a number of CSL-N groups connected by a metal line 551. This can thereby reduce the source line resistance by 1/M.

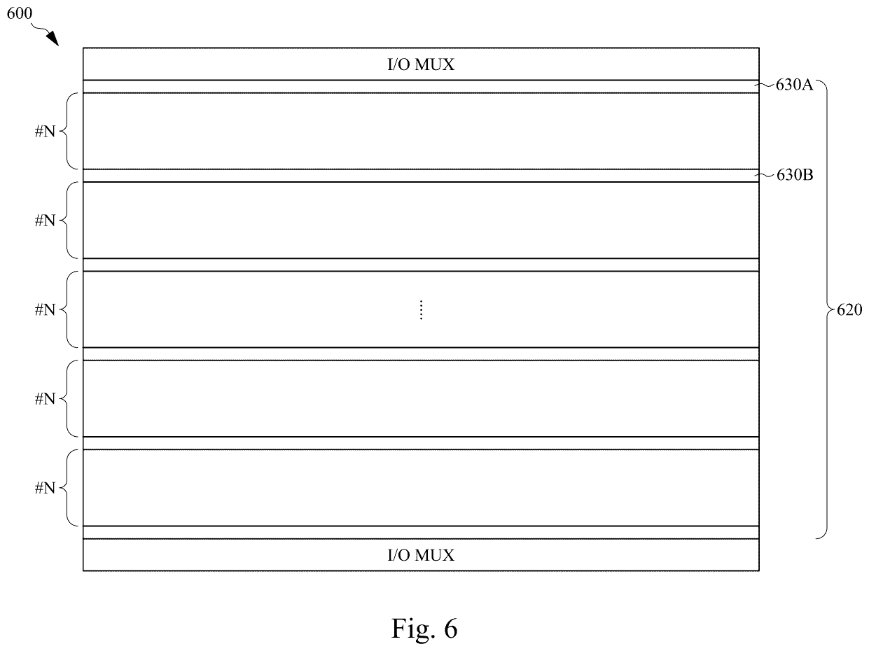

FIG. 6 illustrates a block diagram of an example memory device (or circuit) 600, in accordance with some embodiments. In some embodiments, the memory device 600 may be substantially similar to or incorporate features of the memory device 100, the memory device 200, etc. For example, the memory device 600 includes a memory array 620 and a plurality of additional rows (e.g., a first additional row 630A, a second additional row 630B, etc.), which may be substantially similar to or incorporate features of the memory array 120, etc. and the additional row 230, etc., respectively. It should be appreciated that the memory device 600 of FIG. 6 is simplified for illustrative purposes, and thus, can be implemented as any of various other configurations while remaining within the scope of the present disclosure.

In some embodiments, as opposed to the memory device 200, the memory device 600 can include any number of additional rows. As shown, the memory device can include the plurality of additional rows (e.g., the first additional row 630A, the second additional row 630B, etc.). For example, the memory array 620 can include the additional row per N word lines WLs. That is, the shunt components in each of the plurality of additional rows can be configured to perform shunting operation for a corresponding memory array. For example, the shunt components of each additional row can be configured to receive a shunt enable signal SHT_EN, which can be configured to enable or disable shunting the corresponding source lines with respect to the corresponding memory array. Although depicted as including the additional row per N WLs, in some embodiments, the additional row can be included in various manners. For example, the first additional row 630A can be included for a first number of WLs, while the second additional row 630B can be included for a second number of WLs. This allows the memory array 620 to reduce the SL resistance based on the function and/or performance of the memory array 620.

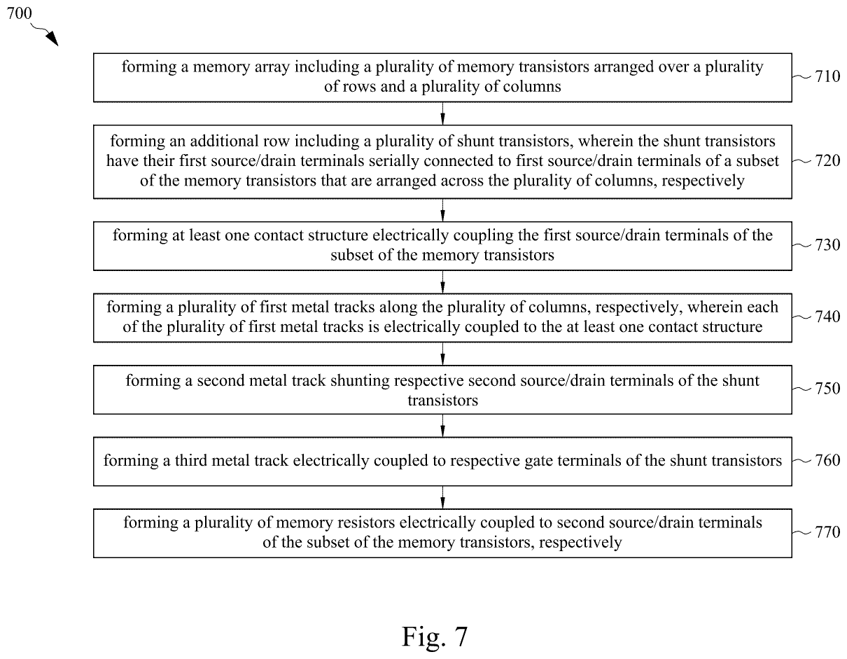

FIG. 7 illustrates a flow chart of an example method 700 for forming a memory device, in accordance with some embodiments. In some embodiments, the method 700 can be performed to form a memory device (e.g., the memory device 100, the memory device 200, etc.), and thus, some of the references used above may be reused in the following discussion of the method 700. It is noted that the method 700 is merely an example and is not intended to limit the present disclosure. Accordingly, it is understood that additional operations may be provided before, during, and after the method 700 of FIG. 7, and that some other operations may only be briefly described herein.

In a brief overview, the method 700 can begin with operation 710 of forming a memory array including a plurality of memory transistors arranged over a plurality of rows and a plurality of columns. The method 700 can continue to operation 720 of forming an additional row including a plurality of shunt transistors, wherein the shunt transistors have their first source/drain terminals serially connected to first source/drain terminals of a subset of the memory transistors that are arranged across the plurality of columns, respectively. The method 700 can continue to operation 730 of forming at least one contact structure electrically coupling the first source/drain terminals of the subset of the memory transistors. The method 700 can continue to operation 740 of forming a plurality of first metal tracks along the plurality of columns, respectively, wherein each of the plurality of first metal tracks is electrically coupled to the at least one contact structure. The method 700 can continue to operation 750 of forming a second metal track shunting respective second source/drain terminals of the shunt transistors. The method 700 can continue to operation 760 of forming a third metal track electrically coupled to respective gate terminals of the shunt transistors. The method 700 can continue to operation 770 of forming a plurality of memory resistors electrically coupled to second source/drain terminals of the subset of the memory transistors, respectively.

At operation 710, a memory array (e.g., the memory array 220) can be formed. The memory array can include a plurality of memory transistors (e.g., the memory transistors 221A, 221B, etc.) arranged over a plurality of rows and a plurality of columns.

At operation 720, an additional row (e.g., the additional row 230) can be formed. The additional row can include a plurality of shunt transistors (e.g., the shunt transistors 231A, 231B, etc.). The shunt transistors can have their first source/drain terminals serially connected to first source/drain terminals of a subset of the memory transistors that are arranged across the plurality of columns, respectively. In some embodiments, the plurality of shunt transistors can be electrically disconnected from respective shunt resistors (e.g., the shunt resistors 232A, 232B, etc.).

At operation 730, at least one contact structure (e.g., MD shown in FIG. 4) can be formed. The at least one contact structure can be formed to electrically couple the first source/drain terminals of the subset of the memory transistors. At operation 740, a plurality of first metal tracks (e.g., CSL[0]) can be formed along the plurality of columns, respectively. Each of the plurality of first metal tracks can be electrically coupled to the at least one contact structure. At operation 750, a second metal track (e.g., SL Shunt) can be formed to shunt respective second source/drain terminals of the shunt transistors. At operation 760, a third metal track (e.g., the metal track 252 shown in FIG. 2) can be formed to be electrically coupled to respective gate terminals of the shunt transistors. In some embodiments, the third metal track can be configured to receive a shunt enable signal (e.g., SHT_EN). In some embodiments, when the shunt enable signal is provided at a first logic state (e.g., “1”), the plurality of shunt transistors can be turned on to electrically couple the second metal track to the plurality of first metal tracks. When the shunt enable signal is provided at a second logic state, the plurality of shunt transistors can be turned off to electrically decouple the second metal track from the plurality of first metal tracks.

At operation 770, a plurality of memory resistors can be formed to be electrically coupled to second source/drain terminals of the subset of the memory transistors, respectively.

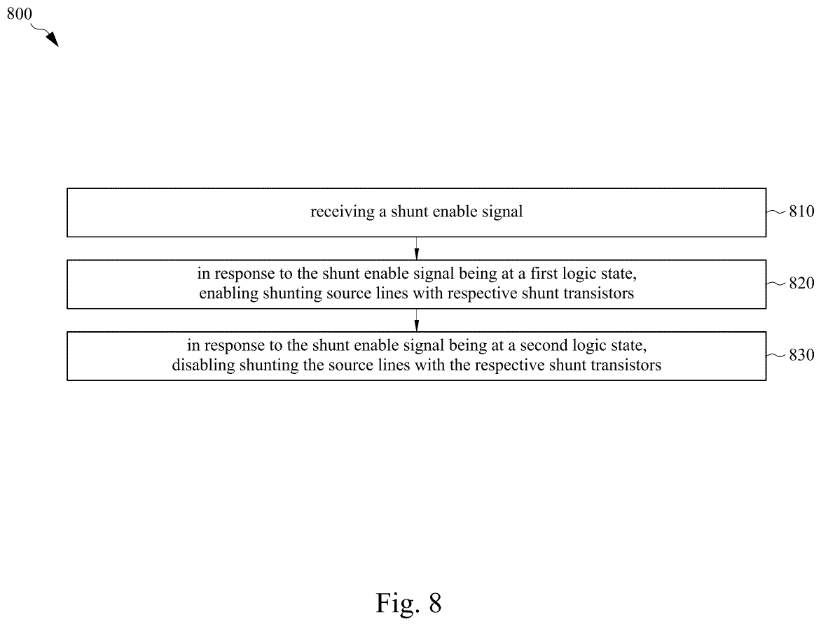

FIG. 8 illustrates a flow chart of an example method 800 for operating a memory device, in accordance with some embodiments. In some embodiments, the method 800 can be performed to operate a memory device (e.g., the memory device 100, the memory device 200, etc.), and thus, some of the references used above may be reused in the following discussion of the method 800. It is noted that the method 800 is merely an example and is not intended to limit the present disclosure. Accordingly, it is understood that additional operations may be provided before, during, and after the method 800 of FIG. 8, and that some other operations may only be briefly described herein.

In a brief overview, the method 800 can begin with operation 810 of receiving a shunt enable signal. The method 800 can continue to operation 820 (in response to the shunt enable signal being at a first logic state, enabling shunting source lines with respective shunt transistors) and/or operation 830 (in response to the shunt enable signal being at a second logic state, disabling shunting the source lines with the respective shunt transistors).

At operation 810, the shunt enable signal (e.g., SHT_EN of FIG. 2) can be received. In some embodiments, the method 800 can include receiving, by respective gate terminals of a plurality of shunt transistors (e.g., the shunt transistors 231A, 231B, etc.), the shunt enable signal.

At operation 820, shunting source lines (e.g., the fourth metal track 254, the fifth metal track 255, etc. of FIG. 3A) can be enabled with respective shunt transistors (e.g., the first shunt transistor 231A, the second shunt transistor 231B, etc. of FIG. 3A), in response to the shunt enable signal being at a first logic state. For example, the method 800 can include enabling shunting the source lines with respective shunt transistors, in response to the shunt enable signal being at “1.” In some embodiments, the first logic state can be configured at “1” when reading memory cells (e.g., the first memory cells 220A) or writing a second logic state to the memory cells. In some embodiments, the method 800 can include electrically coupling a first metal track (e.g., the fourth metal track 254 of FIG. 2) and a second metal track (e.g., the fifth metal track 255 of FIG. 2) to a third metal track (e.g., the first metal track 251 of FIG. 2).

At operation 830, shunting the source lines can be disabled with the respective shunt transistors, in response to the shunt enable signal being at a second logic state. For example, the method 800 can include disabling shunting the source lines with the respective shunt transistors, in response to the shunt enable signal being at “0.” In some embodiments, the first logic state can be configured at “0” when writing the first logic state (e.g., “1”) to the memory cells (e.g., the first memory cells 220A). In some embodiments, the method 800 can include electrically decoupling the first metal track (e.g., the fourth metal track 254 of FIG. 2) and the second metal track (e.g., the fifth metal track 255 of FIG. 2) from the third metal track (e.g., the first metal track 251 of FIG. 2).

In some embodiments, the method 800 can include enabling (e.g., at operation 820) and/or disabling (e.g., at operation 830) shunting to perform various operations and/or functions. For example, the method 800 can include enabling and/or disabling shunting to perform the functions shown in Table 1.

In some embodiments, the method 800 can include enabling and/or disabling shunting to perform the Read/CIM read function. When the shunt enable signal is at a first logic state (e.g., “1”), the bit line voltage V_{BL} is set at V_{read} while the source line voltage V_{SL} is set at 0. In some embodiments, the method 800 can include turning on the controllable SL shunt, in response to the shunt enable signal being at the first logic state. This can reduce the SL resistance and improve the read margin.

In some embodiments, the method 800 can include enabling and/or disabling shunting to perform the Write-0 function. When the shunt enable signal is at a first logic state (e.g., “1”), the bit line voltage V_{BL} is set at V_{write} while the source line voltage V_{SL} is set at 0. In some embodiments, the method 800 can include turning on the controllable SL shunt, in response to the shunt enable signal being at the first logic state. This can reduce the SL resistance and improve the read margin.

In some embodiments, the method 800 can include enabling and/or disabling shunting to perform the Write-1 function. When the shunt enable signal is at a second logic state (e.g., “0”), the bit line voltage V_{BL} is set at 0 while the source line voltage V_{SL} is set at V_{write}. In some embodiments, the method 800 can include turning off the controllable SL shunt to keep the SL capacitance low, thereby improving the speed and power.

In some embodiments, the method 800 can include enabling and/or disabling shunting to perform the Write-BRK function. When the shunt enable signal is at a first logic state (e.g., “1”), the bit line voltage V_{BL} is set at V_{BRK} while the source line voltage V_{SL} is set at 0. In some embodiments, the method 800 can include turning on the controllable SL shunt, in response to the shunt enable signal being at the first logic state. This can reduce the SL resistance and improve the read margin.

In one aspect of the present disclosure, a memory device is disclosed. The memory device includes a memory array including a plurality of first memory cells physically arranged over a plurality of rows and a plurality of first columns. Each of the plurality of first memory cells includes a memory transistor serially coupled to a memory resistor. The memory device includes one additional row arranged next to the memory array. The additional row includes a plurality of first shunt components, and each of the plurality of first shunt components includes a shunt transistor and a shunt resistor. Respective first source/drain terminals of the shunt transistors of the first shunt components are electrically coupled to one another, and respective second source/drain terminals of the shunt transistors of the first shunt components are electrically coupled to one another and further electrically coupled to respective first source/drain terminals of the memory transistors of the first memory cells.

In another aspect of the present disclosure, a memory device is disclosed. The memory device includes a first memory cell including a first memory transistor serially connected to a first memory resistor, wherein the first memory transistor having a first source/drain terminal, a second source/drain terminal, and a gate terminal. The memory device includes a second memory cell including a second memory transistor serially connected to a second memory resistor, wherein the second memory transistor having a first source/drain terminal, a second source/drain terminal, and a gate terminal. The memory device includes a first shunt component including a first shunt transistor and a first shunt resistor, wherein the first shunt transistor having a first source/drain terminal, a second source/drain terminal, and a gate terminal. The memory device includes a second shunt component including a second shunt transistor and a second shunt resistor, wherein the second shunt transistor having a first source/drain terminal, a second source/drain terminal, and a gate terminal. The first source/drain terminal of the first shunt transistor and the first source/drain terminal of the second shunt transistor are electrically couped to each other, the second source/drain terminal of the first shunt transistor is electrically connected to the first source/drain terminal of the first memory transistor, the second source/drain terminal of the second shunt transistor is electrically connected to the first source/drain terminal of the second memory transistor, and the first source/drain terminal of the first memory transistor and the first source/drain terminal of the second memory transistor are electrically coupled to each other.

In yet another aspect of the present disclosure, a method for forming memory devices is disclosed. The method includes forming a memory array including a plurality of memory transistors arranged over a plurality of rows and a plurality of columns, forming an additional row including a plurality of shunt transistors arranged along the plurality of columns, respectively, wherein the shunt transistors have their first source/drain terminals serially connected to first source/drain terminals of a subset of the memory transistors that are arranged across the plurality of columns, respectively, forming at least one contact structure electrically coupling the first source/drain terminals of the subset of the memory transistors, forming a plurality of first metal tracks along the plurality of columns, respectively, wherein each of the plurality of first metal tracks is electrically coupled to the at least one contact structure, forming a second metal track shunting respective second source/drain terminals of the shunt transistors, forming a third metal track electrically coupled to respective gate terminals of the shunt transistors, and forming a plurality of memory resistors electrically coupled to second source/drain terminals of the subset of the memory transistors, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a memory array including a plurality of first memory cells physically arranged over a plurality of rows and a plurality of first columns, wherein each of the plurality of first memory cells includes a memory transistor serially coupled to a memory resistor; and
one additional row arranged next to the memory array, wherein the one additional row includes a plurality of first shunt components, and wherein each of the plurality of first shunt components includes a shunt transistor and a shunt resistor;
wherein respective first source/drain terminals of the shunt transistors of the plurality of first shunt components are electrically coupled to one another, and respective second source/drain terminals of the shunt transistors of the plurality of first shunt components are electrically coupled to one another and further electrically coupled to respective first source/drain terminals of the memory transistors of the plurality of first memory cells.

2. The memory device of claim 1, wherein the shunt transistor and the shunt resistor of each of the plurality of first shunt components are electrically disconnected from each other.

3. The memory device of claim 1, wherein the memory array further includes a plurality of second memory cells arranged over the plurality of rows and a plurality of second columns, wherein each of the plurality of second memory cells includes a memory transistor serially connected to a memory resistor.

4. The memory device of claim 3, wherein the one additional row further includes a plurality of second shunt components, wherein each of the plurality of second shunt components includes a shunt transistor and a shunt resistor, and wherein respective first source/drain terminals of the shunt transistors of the plurality of second shunt components are electrically coupled to one another, and respective second source/drain terminals of the shunt transistors of the plurality of second shunt components are electrically coupled to one another and further electrically coupled to respective first source/drain terminals of the memory transistors of the plurality of second memory cells.

5. The memory device of claim 1, wherein respective gate terminals of the shunt transistors of the plurality of first shunt components are electrically coupled to one another, and are configured to receive a shunt enable signal.

6. The memory device of claim 1, further comprising:
a plurality of source lines electrically coupled to one another and physically arranged along the plurality of first columns, respectively;
wherein each of the plurality of source lines is electrically coupled to the respective first source/drain terminals of the memory transistors of the plurality of first memory cells and to the respective second source/drain terminal of the shunt transistor of the first shunt component, that are arranged along a respective one of the plurality of first columns.

7. The memory device of claim 6, wherein a shunt enable signal is configured at a first logic state to enable shunting the plurality of source lines with the shunt transistors of the plurality of first shunt components, when reading the plurality of first memory cells or writing a second logic state to the plurality of first memory cells.

8. The memory device of claim 7, wherein the shunt enable signal is configured at the second logic state to disable shunting the plurality of source lines with the shunt transistors of the plurality of first shunt components, when writing the first logic state to the plurality of first memory cells.

9. The memory device of claim 1, wherein the plurality of first memory cells each include a magnetoresistive random access memory (MRAM) cell, a resistive random access memory (RRAM) cell, or a phase change random access memory (PCRAM) cell.

10. The memory device of claim 1, wherein adjacent ones of the plurality of first memory cells are commonly connected to a common memory resistor.

11. A memory device, comprising:
a first memory cell including a first memory transistor serially connected to a first memory resistor, wherein the first memory transistor having a first source/drain terminal, a second source/drain terminal, and a gate terminal;
a second memory cell including a second memory transistor serially connected to a second memory resistor, wherein the second memory transistor having a first source/drain terminal, a second source/drain terminal, and a gate terminal;
a first shunt component including a first shunt transistor and a first shunt resistor, wherein the first shunt transistor having a first source/drain terminal, a second source/drain terminal, and a gate terminal; and
a second shunt component including a second shunt transistor and a second shunt resistor, wherein the second shunt transistor having a first source/drain terminal, a second source/drain terminal, and a gate terminal;
wherein the first source/drain terminal of the first shunt transistor and the first source/drain terminal of the second shunt transistor are electrically coupled to each other, the second source/drain terminal of the first shunt transistor is electrically connected to the first source/drain terminal of the first memory transistor, the second source/drain terminal of the second shunt transistor is electrically connected to the first source/drain terminal of the second memory transistor, and the first source/drain terminal of the first memory transistor and the first source/drain terminal of the second memory transistor are electrically coupled to each other.

12. The memory device of claim 11, wherein the first source/drain terminal of the first shunt transistor and the first source/drain terminal of the second shunt transistor are electrically coupled to each other with a first metal track, the gate terminal of the first shunt transistor and the gate terminal of the second shunt transistor are electrically coupled to each other with a second metal track, the gate terminal of the first memory transistor and the gate terminal of the second memory transistor are electrically coupled to each other with a third metal track, the first source/drain terminal of the first memory transistor is electrically coupled to a fourth metal track, and the first source/drain terminal of the second memory transistor is electrically coupled to a fifth metal track.

13. The memory device of claim 12, wherein the fourth metal track and the fifth metal track are arranged in parallel with each other, electrically coupled to each other, and formed in a first metallization layer, and wherein the first metal track to the third metal track are arranged in parallel with one another and formed in a second metallization layer.

14. The memory device of claim 13, wherein the second metal track is configured to receive a shunt enable signal, and the third metal track is configured to receive a word line assertion signal.

15. The memory device of claim 14, wherein when the shunt enable signal is provided at a first logic state, the fourth metal track and the fifth metal track are electrically coupled to the first metal track.

16. The memory device of claim 15, wherein when the shunt enable signal is provided at a second logic state, the fourth metal track and the fifth metal track are electrically decoupled from the first metal track.

17. The memory device of claim 11, wherein the first shunt transistor is electrically disconnected from the first shunt resistor, and the second shunt transistor is electrically disconnected from the second shunt resistor.

18. A method for forming memory devices, comprising:
forming a memory array including a plurality of memory transistors arranged over a plurality of rows and a plurality of columns;
forming an additional row including a plurality of shunt transistors arranged along the plurality of columns, respectively, wherein the plurality of shunt transistors have their first source/drain terminals serially connected to first source/drain terminals of a subset of the plurality of memory transistors that are arranged across the plurality of columns, respectively;
forming at least one contact structure electrically coupling the first source/drain terminals of the subset of the plurality of memory transistors;
forming a plurality of first metal tracks along the plurality of columns, respectively, wherein each of the plurality of first metal tracks is electrically coupled to the at least one contact structure;
forming a second metal track shunting respective second source/drain terminals of the plurality of shunt transistors;
forming a third metal track electrically coupled to respective gate terminals of the plurality of shunt transistors; and
forming a plurality of memory resistors electrically coupled to second source/drain terminals of the subset of the plurality of memory transistors, respectively.

19. The method of claim 18, wherein the third metal track is configured to receive a shunt enable signal.

20. The method of claim 19, wherein
when the shunt enable signal is provided at a first logic state, the plurality of shunt transistors are turned on to electrically couple the second metal track to the plurality of first metal tracks, and
when the shunt enable signal is provided at a second logic state, the plurality of shunt transistors are turned off to electrically decouple the second metal track from the plurality of first metal tracks.
